(19) United States
(12) Patent Application Publication
(10) Pub. No.: US 2025/0006606 A1
(43) Pub. Date: Jan. 2, 2025

(54) SEMICONDUCTOR PACKAGE AND METHOD FOR MANUFACTURING THE SAME

(71) Applicant: Samsung Electronics Co., Ltd., Suwon-si (KR)

(72) Inventors: HYUNJU LEE, Suwon-si (KR); GYUHO KANG, Suwon-si (KR); SUNG KEUN PARK, Suwon-si (KR); KWANGOK JEONG, Suwon-si (KR); JAEMOK JUNG, Suwon-si (KR); JU-IL CHOI, Suwon-si (KR)

(21) Appl. No.: 18/416,008

(22) Filed: Jan. 18, 2024

(30) Foreign Application Priority Data
Jun. 27, 2023 (KR) 10-2023-0082877

(51) Int. Cl. H01L 23/498; H01L 23/00

(52) U.S. Cl. CPC H01L 23/49816; H01L 24/32; H01L 2224/32225; H01L 2924/181

(57) ABSTRACT

A semiconductor package may include: a substrate; a seed layer on a first surface of the substrate; a pad on the seed layer and including a first metal layer and a second metal layer on the first metal layer; an insulating layer on the first surface and including a side surface in contact with the second metal layer; and a semiconductor chip above a second surface of the substrate. An interface between the side surface of the insulating layer and the second metal layer may be nonplanar.

### CROSS-REFERENCE TO RELATED APPLICATION

This application claims priority to and the benefit of Korean Patent Application No. 10-2023-0082877, filed in the Korean Intellectual Property Office on Jun. 27, 2023, the entire contents of which are incorporated herein by reference.

### BACKGROUND

The present disclosure relates to a semiconductor package and a method for manufacturing (fabricating) the same.

A semiconductor package implements a semiconductor chip into a form suitable for use in an electronic product. A process for manufacturing the semiconductor package may include a process in which the semiconductor chip is attached and sealed to an upper surface of a substrate and a solder ball or a solder pad is formed at a lower surface of the substrate. A pad and an insulating layer for protecting the pad and the lower surface of the substrate from external contamination may be disposed at the lower surface of the substrate to bond the solder ball or the solder pad to the substrate. If adhesion between the insulating layer and the pad is insufficient, the insulating layer may be separated from the lower surface of the substrate or the pad in a subsequent process.

### SUMMARY

A problem to be solved by the present disclosure is to provide a semiconductor package with improved adhesion between an insulating layer and a pad and a method for manufacturing the same.

Problems to be solved by embodiments of the present disclosure are not limited to the problem mentioned above, and other problems not mentioned will be clearly understood by those skilled in the art from the following description.

A semiconductor package according to some embodiments of the present disclosure includes: a substrate; and a pad on one surface of the substrate and includes a first metal layer and a second metal layer covering the first metal layer. A side surface of the second metal layer is nonplanar.

A semiconductor package according to some other embodiments of the present disclosure includes: a substrate; a seed layer on a first surface of the substrate; a pad on the seed layer and including a first metal layer and a second metal layer on the first metal layer; an insulating layer on the first surface of the substrate and including a side surface in contact with the second metal layer; and a semiconductor chip above a second surface of the substrate. An interface between the side surface of the insulating layer and the second metal layer is nonplanar.

A method for manufacturing the semiconductor package according to some other embodiments of the present disclosure includes: providing a substrate; forming a seed layer on the substrate; providing a photoresist film including an opening on the seed layer; forming a first metal layer on the seed layer and at a region defined by the opening; forming a gap between the photoresist film and a side surface of the first metal layer; forming a second metal layer that fills the gap and covers the side surface of the first metal layer and an upper surface of the first metal layer on the seed layer; and removing the photoresist film from the substrate. The forming of the gap includes forming a nonplanar surface of the photoresist film.

According to some embodiments, each of a pad and an insulating layer included in a semiconductor package may include a nonplanar structure (or an uneven structure) on a surface thereof. Accordingly, adhesion between the pad and the insulating layer may be improved, so that a phenomenon where the insulating layer is separated from a surface of a substrate or the pad is improved.

According to some embodiments, a method of efficiently forming each of the pad and the insulating layer including the nonplanar structure on the surface thereof at the semiconductor package through a simplified process may be provided.

### BRIEF DESCRIPTION OF THE DRAWINGS

FIG. 1 is a diagram showing a semiconductor package of some embodiments.

FIG. 2 is a plan view showing one surface of a substrate in the semiconductor package of FIG. 1.

FIG. 3A and FIG. 3B are diagrams for describing adhesion (or an adhesive force) between an insulating layer and a pad included in the semiconductor package.

FIG. 4A and FIG. 4B are diagrams for describing a structure of a semiconductor package according to some embodiments.

FIGS. 5 to 11 are diagrams for describing a method for manufacturing a semiconductor package according to some embodiments.

### DETAILED DESCRIPTION

Below, embodiments of the present disclosure will be described with reference to accompanying drawings to such an extent as to be easily realized by a person having an ordinary knowledge in the present disclosure. The present disclosure may be modified in various different ways, without departing from the scope of the present disclosure.

In order to clearly describe the present disclosure, parts or portions that are irrelevant to the description may be omitted, and identical or similar constituent elements throughout the specification are denoted by the same reference numerals.

Further, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” may mean disposed on or below the object portion, and does not necessarily mean disposed on the upper side of the object portion based on a gravitational direction.

In addition, unless explicitly described to the contrary, the words “comprise” and includes and variations such as “comprises” or “comprising” and “including” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package according to some embodiments will be described with reference to the drawings.

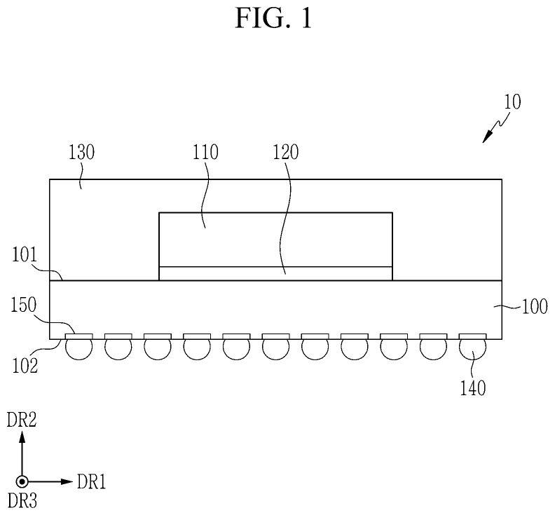

FIG. 1 is a diagram showing a semiconductor package of some embodiments. FIG. 1 is a cross-sectional view, and is a simplified illustration with some configurations omitted.

Referring to FIG. 1, the semiconductor package 10 includes a substrate 100 and a semiconductor chip 110.

The substrate 100 may be provided in a plate shape, and may have a first surface 101 and a second surface 102. Additionally, the substrate 100 may include an interconnection layer electrically connecting the semiconductor chip 110 and a pad (or a connecting member) that will be described below. As an example, the substrate 100 may include a plurality of insulating layers, a plurality of redistribution layers (RDL), and a redistribution structure including a plurality of vias for electrical connection between the redistribution layers.

The semiconductor chip 110 may be mounted above or on the first surface 101 of the substrate 100. For example, the semiconductor chip 110 may be connected to the substrate 100 through a bonding member 120. The bonding member 120 may include various forms (e.g., a solder, a bonding wire, and the like) that electrically connect the semiconductor chip 110 and the substrate 100. In the drawings, a case where one semiconductor chip is disposed above or on the substrate 100 is shown, but the present disclosure is not limited thereto, and a plurality of semiconductor chips 110 may be disposed above or on the substrate 100. For example, the plurality of semiconductor chips 110 may be disposed in a layer in a third direction DR3 above or on the first surface 101 of the substrate 100. For example, the plurality of semiconductor chips 110 may be disposed side by side above or on the first surface 101 of the substrate 100 in a first direction DR1 and/or the third direction DR3. For example, the plurality of semiconductor chips 110 may be disposed side by side in the first direction DR1 and/or the third direction DR3 above or on the first surface 101 of the substrate 100, and some or all of the plurality of semiconductor chips 110 may have a plurality of sub-semiconductor chips stacked in a second direction DR2.

In some embodiments, the semiconductor chip 110 may be a memory semiconductor chip. For example, the semiconductor chip 110 may be a volatile memory semiconductor chip such as a dynamic random access memory (DRAM) or a static random access memory (SRAM), or may be a non-volatile memory semiconductor chip such as a phase-change random access memory (PRAM), a magnetoresistive random access memory (MRAM), a ferroelectric random access memory (FeRAM), or a resistive random access memory (RRAM). For example, the semiconductor chip 110 may be a high bandwidth memory (HBM).

In some embodiments, the semiconductor chip 110 may be a central processing unit (CPU) chip, a graphics processing unit (GPU) chip, or an application processor (AP) chip. An encapsulant 130 that is on and/or encapsulates the semiconductor chip 110 may be included on the first surface 101 of the substrate 100. The encapsulant 130 may include a molding compound, a molding underfill, an epoxy, and/or a resin, and, for example, may be an epoxy molding compound (EMC).

A plurality of connecting members 140 for electrical connection with an external device may be disposed on the second surface 102 of the substrate 100. The connecting members 140 may be disposed in a regular shape such as a lattice shape. The connecting member 140 may be connected to the substrate 100 to be electrically connected to the semiconductor chip 110, and may include an input/output terminal of the semiconductor chip 110.

The connecting member 140 may include solder. In FIG. 1, a solder ball in the form of a protruding ball is shown as an example of the connecting member 140, but the present disclosure is not limited thereto, and the connecting member 140 may be made of a solder pad in the form of a flat pad.

A plurality of pads 150 for connecting the plurality of connecting members 140 may be formed on the second surface 102 of the substrate 100. The pad 150 may include one metal or an alloy thereof. For example, the pad may include copper (Cu) or nickel (Ni).

In some embodiments, the pad 150 may include two or more metals. For example, the pad may be disposed in a layer of two or more metals. For example, the pad may include a first metal layer and a second metal layer covering the first metal layer. In some embodiments, the pad may include a nonplanar structure (or an uneven structure) on a surface thereof. If the pad includes a plurality of metal layers, a surface of a metal layer disposed at an outermost portion of the plurality of metal layers may include the nonplanar structure.

An insulating layer covering the second surface 102 of the substrate 100 and the pad 150 may be disposed above or on the second surface 102 of the substrate 100. The insulating layer may include an insulating material. In an embodiment, a surface of the insulating layer that is in contact with a side surface of the pad 150 may include a nonplanar structure (or an uneven structure) on a surface thereof.

A plating wire for plating the pad 150 may be further formed above or on the second surface 102 of the substrate 100. The pad 150 may be exposed from the insulating material to be connected to the connecting member 140. Since the pad 150 exposed to the outside needs to be plated to prevent the pad exposed to the outside from being oxidized and contaminated, the plating wire may be formed above or on the second surface 102 of the substrate 100 along with the pad 150. After a plating process is completed, some or all of the plating wire may be removed from the substrate 100, or may have a shape in which some or all of the plating wire are disconnected from the pad 150.

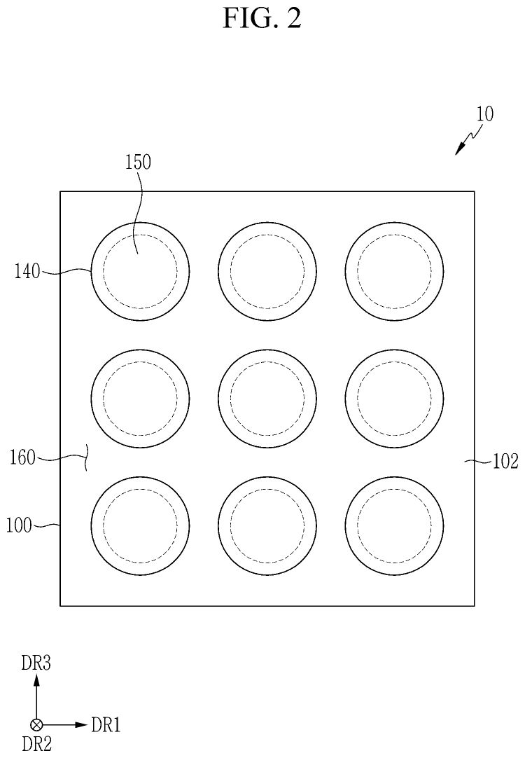

FIG. 2 is a plan view showing one surface of the substrate in the semiconductor package.

Specifically, FIG. 2 may be a plan view of the semiconductor package 10 described with reference to FIG. 1.

Referring to FIG. 2, the plurality of pads 150 and an insulating layer 160 may be formed above or on the second surface 102 of the substrate 100. The connecting member 140 may be disposed on the pad 150.

The plurality of pads 150 may be disposed in a regular shape such as a lattice shape. Referring to FIG. 2, the plurality of pads 150 are shown as disposed in a shape of a 3×3 matrix, but the present disclosure is not limited thereto, and the plurality of pads 150 may be disposed in various numbers and shapes. The pads 150 in the shape of the 3×3 matrix shown in FIG. 2 may represent only some of all pads disposed on the second surface 102 of the substrate 100. The pad 150 may have a circular shape in a plan view, but the present disclosure is not limited thereto, and the pad 150 may have various shapes such as an oval shape, a polygonal shape, and the like. The pad 150 may include one or more metals or an alloy thereof. For example, the pad 150 may include copper (Cu) that is a metal with electrical conductivity. The pads 150 may be patterned on the substrate 100 through a photolithography process and a plating process. For example, the pads 150 on the substrate 100 may be formed by a semi-additive process (SAP). However, a method by which the pads 150 are formed on the substrate 100 is not limited thereto, and the pads 150 may be formed through various methods.

The insulating layer 160 may be intended to protect a surface of the substrate 100 from being exposed. The insulating layer 160 may be disposed on the second surface 102 of the substrate 100 and at a region other than a region in which the plurality of pads 150 are disposed. The insulating layer 160 may contact the side surface of the pad 150 on the substrate 100. The insulating layer 160 may include an insulating material. For example, the insulating layer 160 may include a silicon oxide (SiOₓ) film or a silicon nitride (SiNₓ) film. For example, the insulating layer 160 may include a photo imageable dielectric (PID).

The connecting member 140 may be coupled to the pad 150. The connecting member 140 may be used to electrically connect the semiconductor package 10 to another semiconductor package or another substrate. The connecting member 140 may have a form of a solder ball.

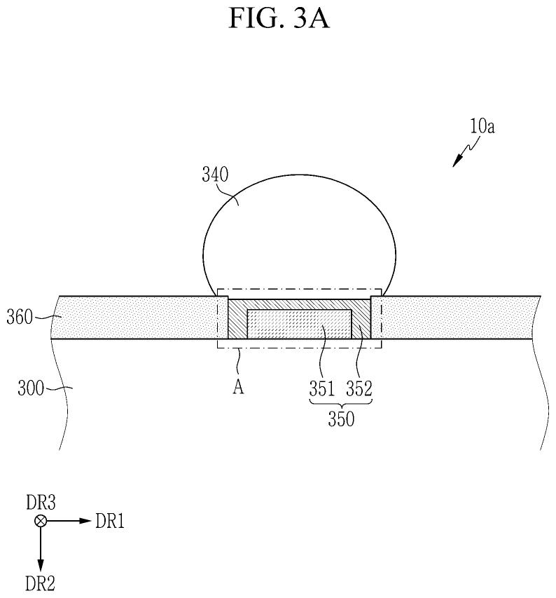

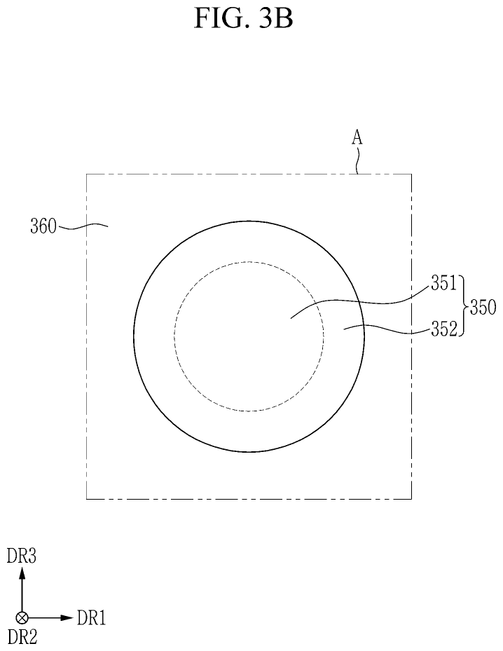

FIG. 3A and FIG. 3B are diagrams for describing adhesion (or an adhesive force) between the insulating layer and the pad included in the semiconductor package.

A semiconductor package 10a shown in FIG. 3A may correspond to a portion of the semiconductor package 10 described with reference to FIGS. 1 and 2. For example, the semiconductor package 10a may include a substrate 300, a pad 350, and an insulating layer 360. The semiconductor package 10a may further include a connecting member 340 disposed on the pad 350. FIG. 3B is a plan view of a region A of FIG. 3A.

Referring to FIG. 3A and FIG. 3B, the pad 350 may be disposed on the substrate 300, and may include two or more thin films. For example, the pad 350 may include a first metal layer 351 and a second metal layer 352 covering or on the first metal layer 351. The insulating layer 360 may be disposed on the substrate 300, and may have a surface in contact with a side surface of the pad 350. The insulating layer 360 may include an insulating material. Referring to FIG. 3A and FIG. 3B, the side surface of the pad 350 in contact with the insulating layer 360 may have a smooth surface. In other words, the surface of the pad 350 in contact with the insulating layer 360 may have very low surface roughness. When the surface roughness of the surface of the pad 350 in contact with the insulating layer 360 is low, adhesion of an interface between the insulating layer 360 and the pad 350 may be deteriorated.

If the adhesion of the interface between the insulating layer 360 and the pad 350 is insufficient, the insulating layer 360 may easily peel off from the substrate 300 or the pad 350 in a subsequent process. For example, if the semiconductor package 10a is exposed to high temperature in the subsequent process, the insulating layer 360 may be peeled off from the substrate 300 or the pad 350. In this case, in a subsequent test process, the semiconductor package 10a may be determined to be defective. Therefore, it may be important to improve the adhesion of the interface between the insulating material included in the insulating layer 360 and the pad 350.

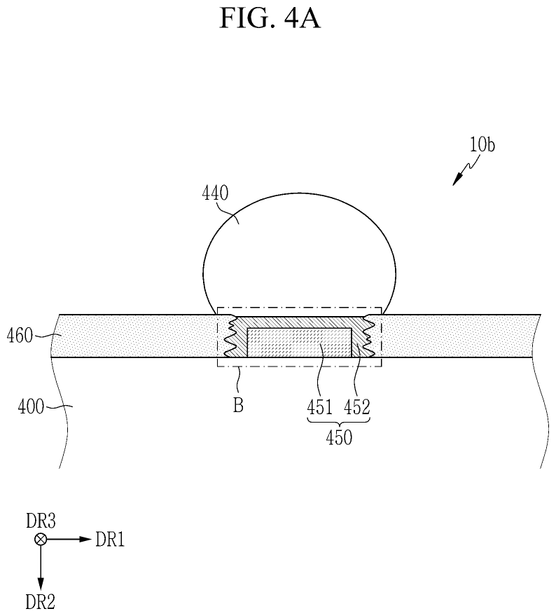

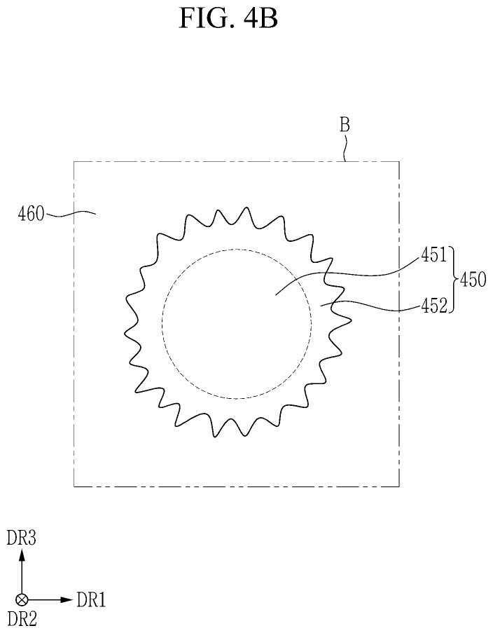

FIG. 4A and FIG. 4B are diagrams for describing a structure of the semiconductor package according to some embodiments.

A semiconductor package 10b shown in FIG. 4A may include a substrate 400, a pad 450, and an insulating layer 460. The semiconductor package 10b may further include a connecting member 440 disposed on the pad 450. FIG. 4B is a plan view of a region B of FIG. 4A.

Referring to FIG. 4A and FIG. 4B, the pad 450 may be disposed on the substrate 400, and may include two or more thin films. For example, the pad 450 may include a first metal layer 451 and a second metal layer 452 covering or on the first metal layer 451. In some embodiments, the first metal layer 451 may include a conductive material such as copper (Cu), aluminum (AI), or titanium (Ti), or an alloy thereof. In some embodiments, the second metal layer 452 may include a conductive material such as nickel (Ni), molybdenum (Mo), titanium (Ti), gold (Au), silver (Au), chromium (Cr), or tin (Sn), or an alloy thereof.

The insulating layer 460 may be disposed on the substrate 400 to have a surface in contact with a side surface of the pad 450. The insulating layer 460 may include an insulating material. In some embodiments, the insulating material may include a silicon oxide (SiOₓ) film or a silicon nitride (SiNₓ) film. In some embodiments, the insulating material may include a photo imageable dielectric (PID).

The side surface of the pad 450 in contact with the insulating layer 460 may have an uneven structure or nonplanar structure. Specifically, an interface between the second metal layer 452 and the insulating layer 460 may have a nonplanar structure. The nonplanar structure may have a shape including a plurality of protrusions on a surface thereof. The plurality of protrusions may be convex regions and there may be a concave region between adjacent ones of the protrusions. The plurality of protrusions formed on the side surface of the pad 450 may have an irregular shape. For example, the side surface of the pad 450 may include a plurality of protrusions having different sizes and shapes. If the side surface of the pad 450 has a nonplanar structure, surface roughness of the side surface of the pad 450 may increase. Referring to FIG. 4A and FIG. 4B, the surface roughness of the side surface of the pad 450 may be greater than surface roughness of the side surface of the pad 350 described with reference to FIGS. 3A and 3B.

In some embodiments, an upper surface of the pad 450 may not have a nonplanar structure. Therefore, the surface roughness of the side surface of the pad 450 may be greater than surface roughness of the upper surface of the pad 450.

In some embodiments, the insulating layer 460 may contact the side surface of the pad 450. A surface of the insulating layer 460 in contact with the side surface of the pad 450 may have a nonplanar structure. That is, an interface between the pad 450 and the insulating layer 460 may have a nonplanar structure. Since a lower surface of the insulating layer 460 in contact with the substrate 400 does not include a nonplanar structure, a surface of the insulating layer 460 in contact with the side surface of the pad 450 may have a higher surface roughness compared with the lower surface of the insulating layer 460.

Referring to FIG. 4A and FIG. 4B, the surface roughness of the side surface of the pad 450 may be high if the side surface of the pad 450 in contact with the insulating layer 460 has a nonplanar structure. When the surface roughness of the surface of the pad 450 in contact with the insulating layer 460 is high, adhesion of the interface between the insulating layer 460 and the pad 450 may be improved.

The semiconductor package 10b described with reference to FIGS. 4A and 4B may have greater surface roughness on the side surface of the pad 450 compared with the semiconductor package 10a described with reference to FIGS. 3A and 3B. Therefore, the semiconductor package 10b described with reference to FIGS. 4A and 4B may have higher adhesion between the pad 450 and the insulating layer 460 compared with the semiconductor package 10a described with reference to FIGS. 3A and 3B. In this case, even if the semiconductor package 10b is exposed to high temperature in a subsequent process, the insulating layer 460 may not be easily peeled off from the substrate 400 or the pad 450.

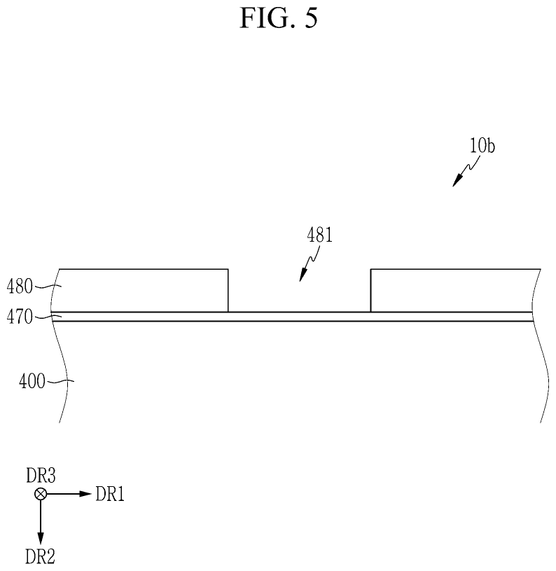

FIGS. 5 to 11 are diagrams for describing a method for manufacturing the semiconductor package according to some embodiments.

Referring to FIG. 5, a seed layer 470 and a photoresist film 480 may be sequentially formed on the substrate 400.

The substrate 400 may be a semiconductor substrate. For example, the substrate 400 may include a semiconductor such as silicon (Si), germanium (Ge), silicon carbide (SiC), gallium arsenide (GaAs), or indium arsenide (InAs). The substrate 400 may be a plate-shaped ceramic substrate or a plate-shaped glass substrate. In some embodiments, the substrate 400 may include a plurality of insulating layers, a plurality of redistribution layers (RDL), and a redistribution structure including a plurality of vias for electrical connection between the redistribution layers.

The seed layer 470 may be formed on the substrate 400. The seed layer 470 may include a conductive material such as copper (Cu), aluminum (Al), or titanium (Ti), or an alloy thereof. The seed layer 470 may be formed on some or all of one surface of the substrate 400. In an embodiment, the seed layer 470 may be formed on the substrate 400 by electroless plating. However, a method by which the seed layer 470 is formed is not limited thereto, and the seed layer 470 may be formed by a physical vapor deposition (PVD) process (e.g., sputtering) or a chemical vapor deposition (CVD) process.

The photoresist film 480 may be formed on the seed layer 470. The photoresist film 480 may be a dry film resist (DRF). The photoresist film 480 may include polyester (PET), a photosensitive film, and polyethylene (PE). The photoresist film 480 may be provided on the seed layer 470 by laminating. The photoresist film 480 may include an opening 481. The opening 481 may be formed at the photoresist film 480 through a photolithography process. For example, after the photoresist film 480 is formed on the seed layer 470, the opening 481 may be formed by performing exposure, baking, and development processes. The opening 481 may expose an upper surface of the seed layer 470.

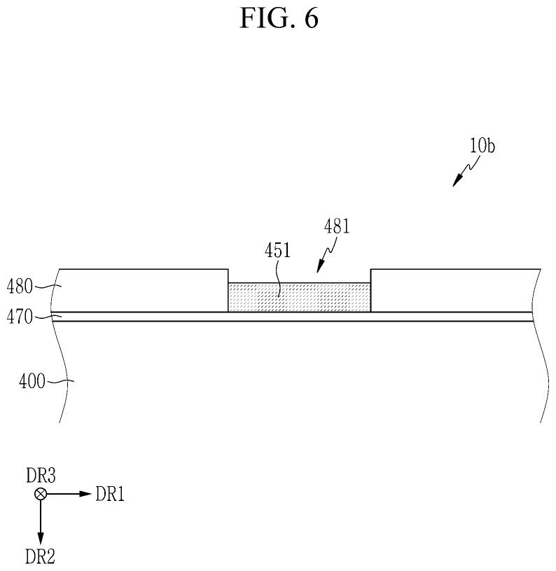

Referring to FIG. 6, the first metal layer 451 may be formed on the seed layer 470 and at a region defined by the opening 481.

The first metal layer 451 may include at least one or more metal material or an alloy. For example, the first metal layer 451 may include a conductive material such as copper (Cu), aluminum (Al), or titanium (Ti), or an alloy thereof. In some embodiments, the first metal layer 451 may include at least one material that is the same as a material included in the seed layer 470. The first metal layer 451 may be formed in the opening 481 of the photoresist film 480 described with reference to FIG. 5. Specifically, the first metal layer 451 may fill or be in an empty space formed on the seed layer 470 as a portion of the photoresist film 480 is opened.

In some embodiments, the first metal layer 451 may be formed on the seed layer 470 by electroplating. However, a method by which the first metal layer 451 is formed is not limited thereto, and the first metal layer 451 may be formed by electroless plating, a physical vapor deposition (PVD) process (e.g., sputtering), or a chemical vapor deposition (CVD) process.

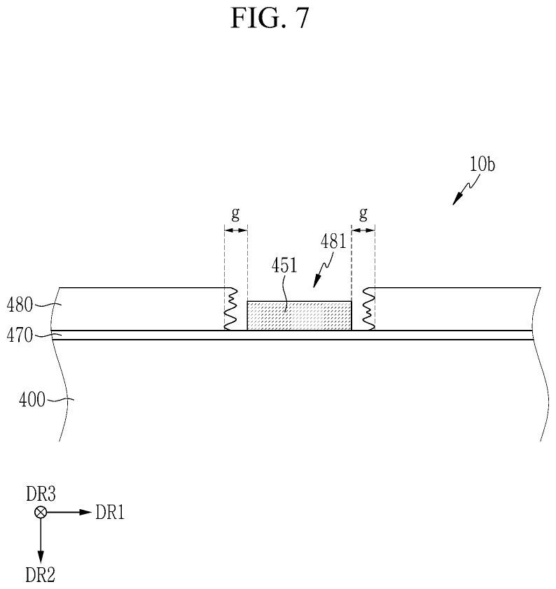

Referring to FIG. 7, after the first metal layer 451 is formed on the seed layer 470, a gap g may be formed between a side surface of the first metal layer 451 and the photoresist film 480. The forming the gap g between the side surface of the first metal layer 451 and the photoresist film 480 may be used to form the second metal layer on the first metal layer 451. For example, if the first metal layer 451 includes a metal material (e.g., copper) that is relatively easy to corrode, the second metal layer including a metal (e.g., nickel) that is relatively difficult to corrode may be formed on the first metal layer 451. Accordingly, it is possible to prevent the first metal layer 451 from being corroded during a process.

In some embodiments, the gap g between the first metal layer 451 and the photoresist film 480 may be formed by heating the semiconductor package 10b provided with the photoresist film 480 and the first metal layer 451. When the dry film resist is heated greater than or equal to a certain temperature, a volume thereof may decrease. In this case, a nonplanar structure may be formed on a surface of the heated dry film resist. In an embodiment, when the photoresist film 480 includes the dry film resist, the gap g may be formed between the photoresist film 480 and the first metal layer 451 as the semiconductor package 10b provided with the photoresist film 480 and the first metal layer 451 is heated under a predetermined temperature and time condition. In this case, a surface of the photoresist film 480 may have a nonplanar structure. In some embodiments, the nonplanar structure formed on the surface of the photoresist film 480 may include at least two or more protrusions. The protrusions formed on the surface of the photoresist film 480 may have an irregular shape. The protrusions formed on the surface of the photoresist film 480 may have various sizes. For example, the nonplanar structure formed on the surface of the photoresist film 480 may include two or more protrusions of different sizes (e.g., different widths or lengths in the first direction DR1 which may be horizontal).

In some embodiments, the semiconductor package 10b may be provided within a chamber where a predetermined pressure condition is maintained to form the gap g between the surface of the photoresist film 480 and the first metal layer 451. When the semiconductor package 10b is heated to a predetermined temperature for a predetermined time within the chamber, the gap g may be formed between the photoresist film 480 and the first metal layer 451. In this case, the surface of the photoresist film 480 may have a nonplanar structure. In some embodiments, a volume of the photoresist film 480 may decrease as a pressure within the chamber in which the semiconductor package 10b is provided is high, a temperature within the chamber is high, and a time for which the semiconductor package 10b is heated is long. In some embodiments, a width of the gap g may increase as the pressure of the chamber in which the semiconductor package 10b is provided is high, the temperature within the chamber is high, and the time for which the semiconductor package 10b is heated is long.

In other embodiments, the gap g between the side surface of the photoresist film 480 and the first metal layer 451 may be formed by selectively etching the first metal layer 451. In this case, the photoresist film 480 or the first metal layer 451 may be anisotropically etched. For example, the gap g may be formed between the side surface of the photoresist film 480 and the first metal layer 451 by anisotropically etching the first metal layer 451 in a state in which the photoresist film 480 and the first metal layer 451 are formed on the seed layer 470.

In other embodiments, the gap g between the side surface of the photoresist film 480 and the first metal layer 451 may be formed by selectively ashing the photoresist film 480.

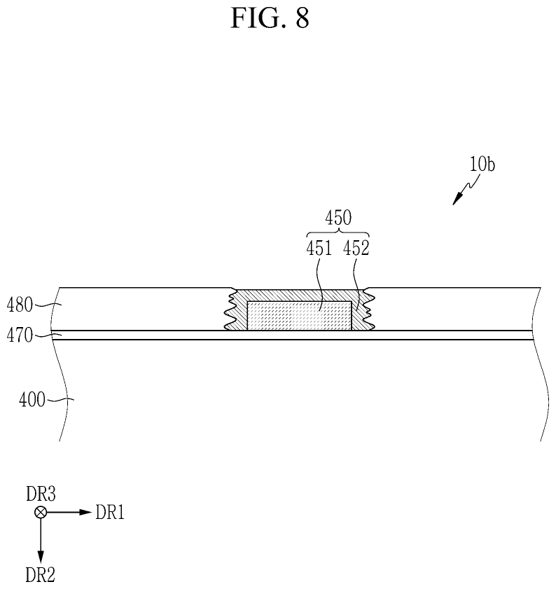

Referring to FIG. 8, after the gap is formed between the side surface of the photoresist film 480 and the first metal layer 451, the second metal layer 452 may be formed on the first metal layer 451. The second metal layer 452 may include a material that is relatively resistant to corrosion compared with a material included in the first metal layer 451. For example, the second metal layer 452 may include nickel (Ni), molybdenum (Mo), titanium (Ti), gold (Au), silver (Au), chromium (Cr), or tin (Sn), or an alloy thereof. The second metal layer 452 may be formed at the opening 481 described with reference to FIGS. 6 and 7. Specifically, the second metal layer 452 may fill or be in the gap formed between the side surface of the photoresist film 480 and the first metal layer 451. The second metal layer 452 may cover or surround side and upper surfaces of the first metal layer 451.

In some embodiments, the second metal layer 452 may be formed on the seed layer 470 by electroplating. However, a method by which the second metal layer 452 is formed is not limited thereto, and the second metal layer 452 may be formed by electroless plating, a physical vapor deposition (PVD) process (e.g., sputtering), or a chemical vapor deposition (CVD) process.

In some embodiments, a side surface of the second metal layer 452 may have a nonplanar structure. That is, since the surface of the photoresist film 480 includes the nonplanar structure and the second metal layer 452 is formed by filling the gap between the photoresist film 480 and the first metal layer 451, the side surface of the second metal layer 452 that contacts the photoresist film 480 may include the nonplanar structure. The nonplanar structure formed on the side surface of the second metal layer 452 may have the same shape as the nonplanar structure formed on the side surface of the photoresist film 480. In some embodiments, the nonplanar structure formed on the side surface of the second metal layer 452 may include at least two or more protrusions. The protrusions formed on the surface of the second metal layer 452 may have an irregular shape. The protrusions formed on the surface of the second metal layer 452 may have various sizes. For example, the nonplanar structure formed on the surface of the second metal layer 452 may include two or more protrusions of different sizes (e.g., different widths or lengths in the first direction DR1 which may be horizontal).

When the pad 450 is plated to prevent oxidation of the pad 450, at least two photolithography processes are generally performed. Specifically, in a first photolithography process, a first photoresist film may be patterned to form a first opening, and then the first metal layer 451 may be formed through a plating process. Thereafter, in a second photolithography process, a second photoresist film may be patterned to form a second opening wider than the first opening, and then the second metal layer 452 may be formed through a plating process. In this case, a process of aligning a mask may be necessary between the first photolithography process and the second photolithography process, and if an interval between pads 450 is very small, there is a possibility that a miss align (or misalignment) may occur. If the miss align occurs in the second photolithography process, the first metal layer 451 may not be completely covered by the second metal layer 452 so that the surface of the first metal layer 451 is exposed to the outside.

In the case of the embodiment described with reference to FIGS. 5 to 8, the pad 450 may be plated using only one photolithography process. Specifically, after the photoresist film 480 provided on the seed layer 470 is patterned to form the opening 481, the first metal layer 451 may be formed through the plating process. Thereafter, after the gap g is formed between the photoresist film 480 and the first metal layer 451 without removing the photoresist film 480, the second metal layer 452 may be formed through the plating process. According to some embodiments, an additional mask alignment process may not be required, so that even when the interval between the pads 450 is very narrow, the second metal layer 452 may be controlled to completely cover the first metal layer 451.

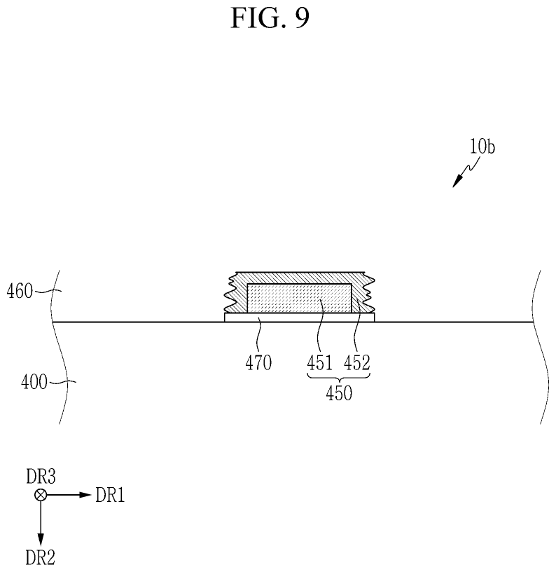

Referring to FIG. 9, after the second metal layer 452 covering the first metal layer 451 is formed on the seed layer 470, the photoresist film may be removed from the substrate 400. After the photoresist film is removed from the substrate 400, a portion of the seed layer 470 may be removed from the substrate. For example, the remaining region excluding a region where the pad 450 is formed at an upper portion of the seed layer 470 among an entire region of the seed layer 470 may be removed from the substrate 400. The portion of the seed layer 470 may be selectively removed by an etching process. For example, if the seed layer 470 includes copper (Cu), the seed layer 470 may be etched using a solution in which sulfuric acid (H₂SO₄) and hydrogen peroxide (H₂O₂) are mixed at a predetermined ratio.

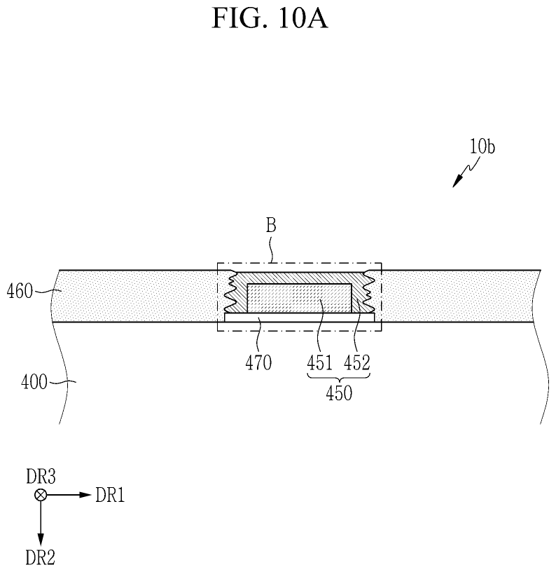

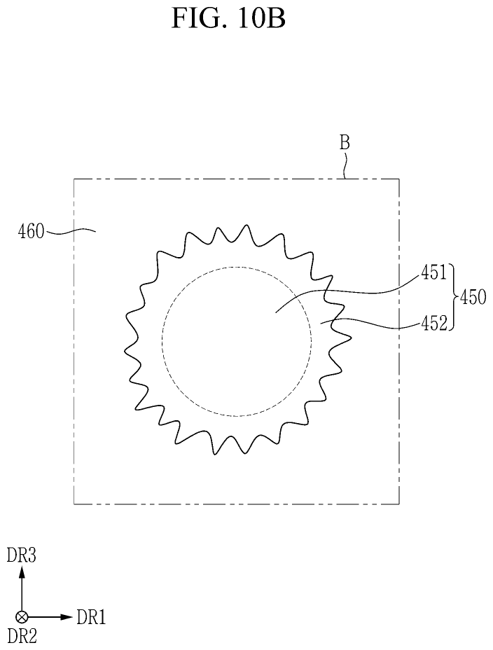

FIG. 10A shows the semiconductor package 10b after a process of forming the insulating layer 460 on the substrate 400 is completed, and FIG. 10B shows a plan view of a region B of FIG. 10A. The insulating layer 460 may be intended to protect the semiconductor package 10b from external contamination. For example, by disposing the insulating layer 460 on the substrate 400, it is possible to prevent a defect from occurring by electrically connecting the pad 450 to a pad adjacent to the pad 450 due to impurities introduced onto the substrate 400 during a process.

In some embodiments, the insulating layer 460 may include an insulating material. For example, the insulating layer 460 may include a photo imageable dielectric (PID). However, the present disclosure is not limited thereto, and the insulating layer 460 may include silicon oxide (SiOₓ) or silicon nitride (SiNₓ).

Referring to FIG. 10A and FIG. 10B, an interface (or a boundary surface) between the pad 450 and the insulating layer 460 may include a nonplanar structure. The nonplanar structure may have an irregular shape. The nonplanar structure may include two or more protrusions of different sizes. If the interface between pad 150 and the insulating layer 460 has the nonplanar structure, adhesion between the pad 150 and the insulating layer 460 may be improved by an anchor effect. Accordingly, a phenomenon where the insulating layer 460 is peeled off from the substrate 400 in the subsequent process may be improved or prevented.

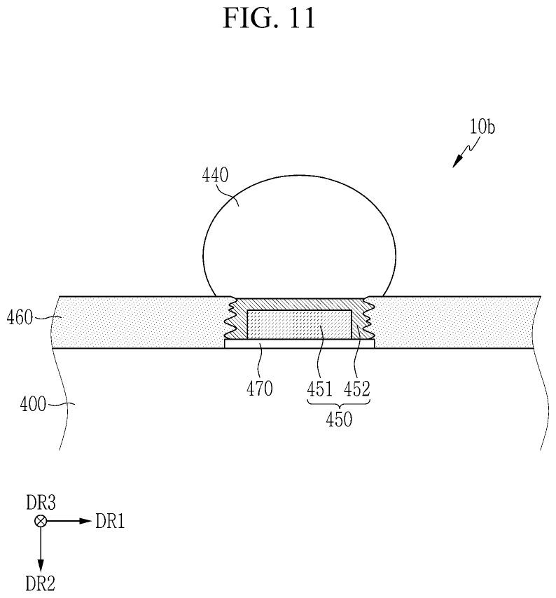

Referring to FIG. 11, after the insulating layer is formed on the substrate 400, the connecting member 440 may be formed on the pad 450. The connecting member 440 may have a form of a solder ball, a solder bump, or a solder pad. Although not shown in the drawings, the connecting member 440 may contact a PCB substrate so that the semiconductor chip 110 described with reference to FIG. 1 and the PCB substrate are electrically connected.

While this disclosure has been described in connection with what is presently considered to be practical embodiments, it is to be understood that the disclosure is not limited to the disclosed embodiments, but, on the contrary, is intended to cover various modifications and equivalent arrangements included within the scope of the appended claims.

What is claimed is:

1. A semiconductor package comprising:
a substrate; and
a pad on one surface of the substrate and includes a first metal layer and a second metal layer covering the first metal layer,
wherein a side surface of the second metal layer is nonplanar.

2. The semiconductor package of claim 1, wherein the side surface of the second metal layer includes two or more protrusions.

3. The semiconductor package of claim 1, wherein the first metal layer includes copper and the second metal layer includes nickel.

4. The semiconductor package of claim 1, wherein a surface roughness of a side surface of the pad is greater than that of an upper surface of the pad.

5. The semiconductor package of claim 1, further comprising an insulating layer on the one surface of the substrate,
wherein a surface of the insulating layer in contact with of a side surface of the pad is nonplanar.

6. The semiconductor package of claim 5, wherein a surface roughness of the surface of the insulating layer in contact with the side surface of the pad is greater than a surface roughness of a surface of the insulating layer in contact with an upper surface of the substrate.

7. The semiconductor package of claim 1, further comprising a seed layer between the substrate and the pad.

8. A semiconductor package comprising:
a substrate;
a seed layer on a first surface of the substrate;
a pad on the seed layer and including a first metal layer and a second metal layer on the first metal layer;
an insulating layer on the first surface of the substrate and including a side surface in contact with the second metal layer; and
a semiconductor chip above a second surface of the substrate,
wherein an interface between the side surface of the insulating layer and the second metal layer is nonplanar.

9. The semiconductor package of claim 8, wherein the first metal layer includes copper and the second metal layer includes nickel.

10. The semiconductor package of claim 8, wherein the substrate includes an interconnection layer that electrically connects the semiconductor chip and the pad.

11. The semiconductor package of claim 8, wherein a side surface of the pad includes two or more protrusions.

12. A method for manufacturing a semiconductor package, comprising:
providing a substrate;
forming a seed layer on the substrate;
providing a photoresist film including an opening on the seed layer;
forming a first metal layer on the seed layer and at a region defined by the opening;
forming a gap between the photoresist film and a side surface of the first metal layer;
forming a second metal layer that fills the gap and covers the side surface of the first metal layer and an upper surface of the first metal layer on the seed layer; and
removing the photoresist film from the substrate,
wherein the forming of the gap includes forming a nonplanar surface of the photoresist film.

13. The method of claim 12, wherein the nonplanar surface of the photoresist film includes two or more protrusions.

14. The method of claim 12, wherein the forming of the nonplanar surface of the photoresist film includes heating the substrate on which the photoresist film, the seed layer, and the first metal layer are disposed.

15. The method of claim 12, further comprising forming an insulating layer in contact with a side surface of the second metal layer on the substrate after the photoresist film is removed,
wherein an interface between the second metal layer and the insulating layer is nonplanar.

16. The method of claim 15, wherein a surface roughness of a surface of the insulating layer in contact with a side surface of a pad is greater than a surface roughness of a surface of the insulating layer in contact with an upper surface of the substrate.

17. The method of claim 12, wherein the photoresist film includes a dry film resist.

18. The method of claim 12, wherein when the photoresist film is heated, a volume of the photoresist film decreases.

19. The method of claim 12, wherein when the photoresist film is heated, the nonplanar surface is formed on the photoresist film.

20. The method of claim 16, wherein a surface roughness of a side surface of the pad is greater than that of an upper surface of the pad.
